(19) United States
(12) Patent Application Publication
(10) Pub. No.: US 2016/0300632 A1
(43) Pub. Date: Oct. 13, 2016

(54) TRANSPARENT CONDUCTIVE FILM AND MANUFACTURING METHOD THEREOF

(71) Applicant: NITTO DENKO CORPORATION, Ibaraki-shi, Osaka (JP)

(72) Inventors: Rie Kawakami, Osaka (JP); Tomotake Nashiki, Osaka (JP); Nozomi Fujino, Osaka (JP); Kazuaki Sasa, Ibaraki-shi (JP); Hironobu Machinaga, Osaka (JP); Manami Kurose, Ibaraki-shi (JP); Tomoya Matsuda, Ibaraki-shi, Osaka (JP)

(73) Assignee: NITTO DENKO CORPORATION, Ibaraki-shi, Osaka (JP)

(21) Appl. No.: 15/036,250

(22) PCT Filed: May 15, 2015
(86) PCT No.: PCT/JP2015/063997

§ 371 Date: May 12, 2016

(30) Foreign Application Priority Data
May 20, 2014 (JP) 2014-104184

(51) Int. Cl. H01B 1/02; C23C 14/08; C23C 14/58; C23C 14/35

(52) U.S. Cl. CPC H01B 1/02; C23C 14/35; C23C 14/086; C23C 14/5806

(57) ABSTRACT

A transparent conductive film includes a polymeric film substrate and a transparent conductive layer on at least one of main surfaces of the polymeric film substrate. The transparent conductive layer is a crystalline transparent conductive layer comprising an indium tin composite oxide. The transparent conductive layer has a residual stress of less than or equal to 600 MPa. The transparent conductive layer has a specific resistance of 1.1×10⁻⁴ Ω·cm to 3.0×10⁻⁴ Ω·cm. The transparent conductive layer has a thickness of 15 nm to 40 nm.

### TECHNICAL FIELD

The present invention relates to a transparent conductive film having a crystalline transparent conductive layer on a polymeric film substrate, and a manufacturing method thereof.

### BACKGROUND ART

Transparent conductive films including a transparent conductive layer such as an ITO layer (indium tin composite oxide layer) formed on a polymeric film substrate are widely utilized for touch panels or the like. Recently, due to an increase in the screen size and a decrease in the thickness of a panel, there is a need for an ITO layer to have an even lower specific resistance and a reduced film thickness.

With a thin ITO layer, in order to achieve a surface resistance value equivalent to those of conventional ITO layers, it is necessary to increase crystallinity of the ITO layer to further decrease the specific resistance. Since an ITO layer having a high crystallinity is poor in flexibility, with a transparent conductive film having a thin ITO layer, cracks generally tend to occur in surface of the ITO layer due to a load by bending, in a conveying process during the manufacture or in a touch panel assembling process. Cracks that have occurred in a surface of the ITO layer causes a significant increase in specific resistance increases and impairs characteristics of the ITO layer.

For example, as a transparent conductive film having an ITO layer formed on a polymeric film substrate, a transparent conductive film in which an ITO layer has a compressive residual stress of 0.4 to 2 GPa has been suggested (Patent Document 1).

### DOCUMENT LIST

### Patent Document(s)

Patent Document 1: Japanese Laid-Open Patent Publication No. 2012-150779

### SUMMARY OF INVENTION

### Technical Problem

Patent Document 1, however, merely has for its object to improve a touch point characteristic under a heavy load and discloses a configuration of applying a high compressive residual stress, and does not disclose an object of preventing occurrence of cracks during the manufacture. Further, an ITO layer of a transparent conductive film disclosed in Patent Document 1 has a very high specific resistance of 6.0×10⁻⁴ Ω·cm.

It is an object of the invention to provide a transparent conductive film having features that a transparent conductive layer has a low specific resistance and a small thickness, while having an excellent crack resistance, and a manufacturing method thereof.

### Solution to Problem

In order to achieve the aforementioned object of the invention, a transparent conductive film of the present disclosure is a transparent conductive film that comprises a polymeric film substrate, and a transparent conductive layer on at least one of main surfaces of the polymeric film substrate, in which the transparent conductive layer is a crystalline transparent conductive layer comprising an indium tin composite oxide, the transparent conductive layer has a residual stress of less than or equal to 600 MPa, the transparent conductive layer has a specific resistance of 1.1×10⁻⁴ Ω·cm to 3.0×10⁻⁴ Ω·cm, and the transparent conductive layer has a thickness of 15 nm to 40 nm.

It is preferable that the transparent conductive layer has a specific resistance of 1.1×10⁻⁴ Ω·cm to 2.2×10⁻⁴ Ω·cm.

It is preferable that the transparent conductive layer is a layer obtained by crystallizing, by heat treatment, an amorphous transparent conductive layer provided on the polymeric film substrate and a maximum rate of dimensional change of the transparent conductive layer in a plane thereof is −1.0% to 0% with respect to the amorphous transparent conductive layer.

It is preferable that the transparent conductive film has an elongated shape and is wound into a roll.

It is preferable that the amorphous transparent conductive layer is crystallized at 110 to 180° C. for less than or equal to 150 minutes.

It is preferable that the transparent conductive layer has a ratio of tin oxide of 0.5% to 15% by weight, the ratio of tin oxide being represented by {tin oxide/(indium oxide+tin oxide)}×100(%).

It is preferable that the transparent conductive layer is a double layered film including a first indium-tin composite oxide layer and a second indium-tin composite oxide layer laminated in this order from the polymeric film substrate side, the first indium-tin composite oxide layer has a tin oxide content of 6% to 15% by weight, and the second indium-tin composite oxide layer has a tin oxide content of 0.5% to 5.3% by weight.

It is preferable that the transparent conductive layer is a triple layered film including a first indium-fin composite oxide layer, a second indium-tin composite oxide layer and a third indium-tin composite oxide layer laminated in this order from the polymeric film substrate side, the first indium-tin composite oxide layer has a fin oxide content of 0.5% to 5.5% by weight, the second indium-tin composite oxide layer has a tin oxide content of 6% to 15% by weight, and the third indium-tin composite oxide layer has a tin oxide content of 0.5% to 5.5% by weight.

It is preferable that an organic dielectric layer formed by a wet film forming method is provided on at least one of the main surfaces of the polymeric film substrate, and the transparent conductive layer is provided on the organic dielectric layer.

It is preferable that an inorganic dielectric layer formed by a vacuum film formation method is provided on at least one of the main surfaces of the polymeric film substrate and the transparent conductive layer is provided on the inorganic dielectric layer.

It is preferable that an organic dielectric layer formed by a wet film formation method, an inorganic dielectric layer formed by a vacuum film formation method, and the transparent conductive layer are provided on at least one of the main surfaces of the polymeric film substrate in this order.

A method of manufacturing a transparent conductive film of the present invention is a method of manufacturing a transparent conductive film including a polymeric film substrate and a transparent conductive layer on at least one of main surfaces of the polymeric film substrate, the transparent conductive layer being a crystalline transparent conductive layer comprising an indium tin composite oxide, the transparent conductive layer having a residual stress of less than or equal to 600 MPa, the transparent conductive layer having a specific resistance of 1.1×10⁻⁴ Ω·cm to 3.0×10⁻⁴ Ω·cm, the transparent conductive layer having a thickness of 15 nm to 40 nm, the method comprising a layer forming step of forming an amorphous transparent conductive layer on the polymeric film substrate by a magnetron sputtering method using a target of an indium tin composite oxide with a horizontal magnetic field at a surface of the target being greater than or equal to 50 mT, and a crystallizing step of crystallizing the amorphous transparent conductive layer by heat treatment.

It is preferable that, in the layer forming step, the amorphous transparent conductive layer is formed on the polymeric film substrate by a RE superposition DC magnetron sputtering method using a target of an indium tin composite oxide with a horizontal magnetic field at a surface of the target being greater than or equal to 50 mT.

It is preferable that the method further comprises a step of heating the polymeric film substrate before the layer formation step.

### Effects of Invention

According to the present invention, it has features that a crystalline transparent conductive layer has a low specific resistance and a small thickness, while having an excellent crack resistance during the manufacture. Particularly even in a case where the transparent conductive film is manufactured by a roll-to-roll method, cracks do not occur in a surface of the crystalline transparent conductive layer, and thus an excellent crack resistance is obtained.

### BRIEF DESCRIPTION OF DRAWINGS

FIG. 1 is a cross sectional view schematically showing a configuration of a transparent conductive film according to an embodiment of the present invention.

### DESCRIPTION OF THE EMBODIMENTS

Hereinafter, embodiments of the present invention will be described in detail with reference to the attached drawings.

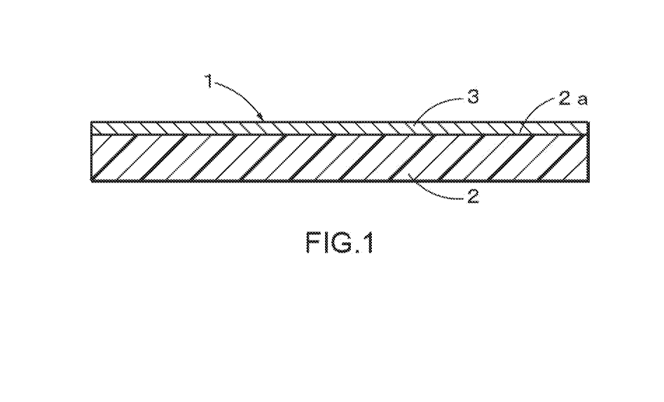

FIG. 1 is a diagram schematically showing a configuration of a transparent conductive film according to the present embodiment. The length, the width and the thickness of each constituent element in FIG. 1 are shown by way of example, and the length, the width and the thickness of each constituent element in a transparent conductive film of the present invention are not limited to those illustrated in FIG. 1.

As illustrated in FIG. 1, a transparent conductive film 1 of the present embodiment has a polymeric film substrate 2, and a transparent conductive layer 3 provided on a main surface 2a of the polymeric film substrate 2. The transparent conductive film 1 has an elongated shape and may be wound into a roll.

Herein, an elongated shape is defined as a shape having a longitudinal dimension, which is a dimension along a longitudinal direction of the film, that is sufficiently greater than a transverse dimension, which is a dimension along a transverse direction of the film, and, in general, a ratio of the longitudinal dimension to the transverse dimension is greater than or equal to 10.

The longitudinal dimension of the transparent conductive film may be a dimension determined as appropriate depending on the type of use of the transparent conductive film, and it is preferably a dimension suitable for a roll-to-roll conveying process. Specifically, it is preferable that the longitudinal dimension is greater than or equal to 10 m.

An amount of the transparent conductive film of the present invention wound into a roll is not particularly limited, and should be determined as appropriate depending on the type of use of the transparent conductive film. The transparent conductive film of the present invention has a high crack resistance, and thus even if wound into a roll, cracks due to a stress such as a bending stress are less likely to occur.

The transparent conductive layer 3 is a crystalline transparent conductive layer comprising an indium tin composite oxide, and has a residual stress of less than or equal to 600 MPa, a specific resistance of 1.1×10⁻⁴ Ω·cm to 3.0×10⁻⁴Ω·cm, and a thickness of 15 nm to 40 nm.

The transparent conductive film configured as described above has a high flexibility, since the transparent conductive layer has a residual stress of less than or equal to 600 MPa. Therefore, the transparent conductive layer has a very low specific resistance of 1.1×10⁻⁴ Ω·cm to 3.0×10⁻⁴ Ω·cm and the transparent conductive layer has a very small thickness of 15 nm to 40 nm, and in addition, crack resistance during the manufacture is excellent. Particularly, when manufacturing the transparent conductive film by a roll-to-roll method, the transparent conductive film is wound into a roll, and thus cracks were likely to occur in a surface of the transparent conductive layer. However, in the present embodiment, the transparent conductive layer has a residual stress of less than or equal to 600 MPa and has an excellent flexibility, and thus cracks can be prevented from occurring.

Now, details of each constituent element of the transparent conductive film 1 will be described below.

(1) Polymeric Film Substrate

The material of a polymeric film substrate is not particularly limited as long as it has transparency, and may include, for example: polyester resins such as polyethylene terephthalate, polybutylene terephthalate, and polyethylenenaphthalate; polyolefin resins such as polycycloolefin; polycarbonate resin; polyamide resins; polyimide resins, cellulosic resins; and polystyrenic resins. The polymeric film substrate has a thickness of preferably 2 μm to 200 μm, more preferably 2 μm to 150 μm, and further preferably 20 μm to 150 μm. When the polymeric film substrate has a thickness of less than 2 μm there may be a case where the polymeric film lacks mechanical strength and makes it difficult to carry out an operation of continuously forming a transparent conductive layer with the polymeric film substrate being wound in a roll shape. On the other hand, when the thickness of the polymeric film substrate exceeds 200 μm, there may be a case where improvement in an anti-scratch property of the transparent conductive layer or a touch point characteristic for a case where a touch panel is formed, cannot be achieved.

(2) Transparent Conductive Layer

The transparent conductive layer comprises indium tin composite oxide (ITO). It is preferable for the content of tin oxide in the indium tin composite oxide to be 0.5% by weight to 15% by weight with respect to a total of indium oxide and tin oxide of 100% by weight. When the content of tin oxide is less than 0.5% by weight, the specific resistance is less likely to decrease when an amorphous ITO is heated, and there may be a case where a transparent conductive layer of a low resistance cannot be obtained. When the content of tin oxide exceeds 15% by weight, tin oxide tends to serve as an impurity and obstruct crystallization. Therefore, when the content of tin oxide is too high, there is a tendency that it becomes difficult to obtain a fully crystallized ITO film or requires time for crystallization, and thus there may be a case where a transparent conductive layer having a high transparency and a low resistance is not obtained.

“ITO” as used herein merely needs to be a composite oxide including at least In and Sn, and may include additional components other than these. An additional component may be, for example, a metallic element other than In and Sri, and specifically, Zn, Ga, Sb, Ti, Si, Zr, Mg, Al, Au, Ag, Cu, Pd, W, Fe, Pb, Ni, Nb, Cr and combinations thereof. The content of an additional component is not particularly limited, and may be less than or equal to 3% by weight.

The transparent conductive layer may have a structure in which a plurality of indium-tin composite oxide layers of mutually different content of tin are laminated. With the transparent conductive layer having such a particular layer structure, it is possible to achieve a further reduction in crystallization time and a further decrease in resistance of the transparent conductive layer.

According to an embodiment of the invention, the transparent conductive layer may be a double layered film including a first indium-tin composite oxide layer and a second indium-tin composite oxide layer laminated in this order from the polymeric film substrate side. It is preferable that the first indium-tin composite oxide layer has a tin oxide content of 6% to 15% by weight, and the second indium-tin composite oxide layer has a tin oxide content of 0.5% to 5.5% by weight. With a double layered film configuration, the crystallization time of the transparent conductive layer can be shortened.

According to an embodiment of the invention, the transparent conductive layer may be a triple layered film including a first indium-tin composite oxide layer, a second indium-tin composite oxide layer and a third indium-tin composite oxide layer laminated in this order from the polymeric film substrate side. It is preferable that the first indium-tin composite oxide layer has a tin oxide content of 0.5% to 5.5% by weight, the second indium-tin composite oxide layer has a tin oxide content of 6% to 15% by weight, and the third indium-tin composite oxide layer has a tin oxide content of 0.5% to 5.5% by weight. With a triple layered film configuration, the specific resistance of the transparent conductive layer can he further decreased.

The transparent conductive layer has a residual stress of less than or equal to 600 MPa, and preferably less than or equal to 550 MPa. When the residual stress exceeds 600 MPa, the flexibility decreases. The residual stress can he calculated based on lattice strain ε, which is obtained from a diffraction peak in X-ray powder diffraction, and on a modulus of elasticity (Young's modulus) E and Poisson's ratio υ.

The transparent conductive layer has a specific resistance of 1.1×10⁻⁴ Ω·cm to 3.0×10⁻⁴ Ω·cm, more preferably 1.1×10⁻⁴ Ω·cm to 2.8×10⁻⁴ Ω·cm, yet more preferably 1.1×10⁻⁴ Ω·cm to 2.4×10⁻⁴ Ω·cm. and further preferably 1.1×10⁻⁴ Ω·cm to 2.2×10⁻⁴ Ω·cm.

The transparent conductive layer has a thickness of 15 nm to 40 nm, and preferably 15 nm to 35 nm. With a thickness of less than 15 nm, it is difficult for the ITO film to crystallize by heating, and it becomes difficult to obtain a transparent conductive layer having a low specific resistance. On the other hand, with a thickness of greater than 40 nm, cracks are likely to occur in the film when the transparent conductive layer is flexed, and it is also disadvantageous in its material cost.

The transparent conductive layer according to the present invention is a crystalline transparent conductive layer that is obtained by performing a crystallizing process on an amorphous transparent conductive layer. The crystalline transparent conductive layer may partly include an amorphous material, but it is preferable that an entirety of the indium-tin composite oxide in the layer is crystalline. In other words, it is preferable that it is completely crystallized. As discussed below, the crystalline transparent conductive layer can be obtained by heating an amorphous transparent conductive layer.

Crack resistance of the crystalline transparent conductive layer can be evaluated by measuring a rate of change of the specific resistance value before and after a flexure test. The flexure test may be performed by any method that applies a load of a certain bending stress or higher to the transparent conductive layer, and, for example, a technique such as bending a transparent conductive film by winding it around a tubular body may be used. Concerning a quantitative evaluation of the transparent conductive layer it is preferable that a sample of a transparent conductive film used for evaluating the crack resistance has a transparent conductive layer for which crystallization has been completed in advance by a sufficient heat treatment.

Note that, “crack resistance” as used herein solely refers to crack resistance of the crystalline transparent conductive layer which has been subjected to a crystallization process, and by no means limits the characteristic of an amorphous transparent conductive layer before the crystallization.

(3) Method of Manufacturing a Transparent Conductive Film

The method of manufacturing the transparent conductive film of the present embodiment is not particularly limited, but preferably has a step of forming an amorphous transparent conductive layer on a polymeric film substrate by a RF superposition DC magnetron sputtering method and a step of crystallizing the amorphous transparent conductive layer by heat treatment.

First, an indium tin composite oxide target and a polymeric film substrate are set in a sputtering apparatus, and an inert gas such as argon is introduced into the sputtering apparatus. It is preferable that the quantity of tin oxide in the target is 0.5% to 15% by weight with respect to the weight of a sum of indium oxide and tin oxide. Further, the target may include elements other than tin oxide and indium oxide. Other elements may be, for example, Fe, Pb, Ni, Cu, Ti and Zn.

Next, sputtering is performed by simultaneously applying an RF power and a DC power to the target to form an amorphous transparent conductive layer on the polymeric film substrate. When a magnetron sputtering method is used, it is preferable that a horizontal magnetic field at a surface of the target is greater than or equal to 50 mT. In a case where the frequency of the RF power is 13.56 MHz, it is preferable that a power ratio of RF power/DC power is 0.4 to 1.0. Also, it is preferable that the temperature of the polymeric film substrate during layer formation is 110° C. to 180° C.

The type of a power supply provided in the sputtering apparatus is not particularly limited, and may be a DC power source, a MF power source, a RF power source, or a combination of any of these power sources. Discharge voltage (absolute value) is preferably 20 V to 350 V, and more preferably, 40 V to 300 V, and further preferably, 40 V to 200 V. By setting to these ranges, an amount of impurities taken into the transparent conductive layer can be decreased, while ensuring a deposition rate of the transparent conductive layer.

Thereafter, the polymeric film substrate on which an amorphous transparent conductive layer is formed is removed from the sputtering apparatus, and heat treatment is performed. This heat treatment is performed for crystallizing the amorphous transparent conductive layer. The heat treatment is performed, for example, using an infrared heater, an oven, or the like.

Normally, heating time of the heat treatment can be set as appropriate within a range of 10 minutes to 5 hours, and considering the productivity in an industrial application, it is, in practice, preferably 10 minutes to 150 minutes, more preferably 10 minutes to 120 minutes. Further, it is preferably 10 minutes to 90 minutes, and more preferably 10 minutes to 60 minutes, and particularly preferably 10 minutes to 30 minutes. By setting the heating time to the aforementioned ranges, crystallization can be positively completed while ensuring, the productivity.

The heating temperature of the heat treatment may be set as appropriate such that crystallization can be achieved, and may generally be 110° C. to 180° C. Considering that a polymeric film substrate commonly used in the art is used, 110° C. to 150° C. is preferable, and 110° C. to 140° C. is further preferable. Depending on the type of a polymeric film substrate, an excessively high heating temperature may cause an unfavorable outcome in a transparent conductive film to be obtained. Specifically, such an unfavorable outcome may be, in a case of a PET film, precipitation of oligomer due to heating, and, in a case of a polycarbonate film or a polycycloolefin film, film composition deformation due to an excess over the glass transition point.

The amorphous transparent conductive layer crystallizes by heat treatment. The maximum rate of dimensional change in a plane of the obtained crystalline transparent conductive layer with respect to the transparent conductive layer before crystallization is preferably −1.0% to 0%, more preferably −0.8% to 0%, and further preferably −0.5% to 0%. Herein, the maximum rate of dimensional change is defined as a value of the rate of dimensional change for a specific direction that has the greatest value among the rates of dimensional change of randomly selected directions, the rate of dimensional change being calculated using an equation represented by:

100×(L−L₀)/L₀,

where L₀ is a distance between two points before the heat treatment on the transparent conductive layer, and L is a distance between two points after the heat treatment corresponding to the distance between the above-mentioned distance between two points. In other words, it can be said that the maximum rate of dimensional change is a rate of dimensional change in a direction of maximum dimensional change in a plane of transparent conductive layer. In general, for a transparent conductive film having an elongated shape, the direction of maximum dimensional change is a conveying direction (MD direction). When the maximum rate of dimensional change is in the aforementioned range, the stress due to dimensional change is small, and thus the crack resistance can be easily improved.

Note that the amorphous transparent conductive layer may be crystallized without separately carrying out a heat treatment as described above. In such a case, the temperature of the polymeric film substrate during layer formulation is preferably greater than or equal to 150° C. Further, in a case where the frequency of the RF power is 13.56 MHz, the power ratio of RF power/DC power is preferably 0.4 to 1.

Also, before forming the amorphous transparent conductive layer on the polymeric film substrate, it is preferable to carry out a process of heating the polymeric film substrate in advance (pre-annealing). By carrying out such a pre-annealing process, the stress in the polymeric film substrate is relaxed and shrinkage of the polymeric film substrate clue to the heating in a process such as a crystallization process will be less likely to occur. By the pre-annealing process, an increase in the residual stress due to thermal shrinkage of the polymeric film substrate can be suppressed appropriately.

It is preferable that the pre-annealing process is carried out in an environmental close to an actual crystallization process step. In other words, it is preferably performed while conveying the polymeric film substrate in a roll-to-roll manner. The heating temperature is preferably 140° C. to 200° C. Further, the heating time is preferably two to five minutes.

According to the present embodiment, a transparent conductive film 1 has a polymeric film substrate 2, and a transparent conductive layer 3 formed a main surface 2a of the polymeric film substrate 2. The transparent conductive layer 3 is a crystalline transparent conductive layer comprising an indium tin composite oxide, and, has a residual stress of less than or equal to 600 MPa, a specific resistance of 1.1×10⁻⁴ Ω·cm to 3.0×10⁻⁴ Ω·cm, and a thickness of 15 nm to 40 nm. Since the residual stress of the transparent conductive layer is less than or equal to 600 MPa, it has an excellent flexibility, and thus, when manufacturing the transparent conductive film, cracks can be prevented from occurring in a surface of the transparent conductive layer in a conveying process or in a touch panel assembly process. Also, in a case where the transparent conductive film is manufactured using a roll-to-roll technique the transparent conductive film is wound into a roll, and thus a bending load is applied on a surface of the transparent conductive layer. However, the transparent conductive film of the present embodiment has an excellent flex durability and can withstand the bending load. Further, since the transparent conductive film of the present embodiment is applicable to touch panels or the like, and particularly, since the specific resistance of the transparent conductive layer is very low and the thickness is very small, it can be adapted to touch panels or the like having a larger screen size and a reduced thickness.

Also, according to the present embodiment, the transparent conductive film 1 is manufactured by a magnetron sputtering method using a target of an indium tin composite oxide, by forming an amorphous transparent conductive layer on the polymeric film substrate 2 with a horizontal magnetic field on a surface of the target surface being greater than or equal to 50 mT, and thereafter crystallizing the amorphous transparent conductive layer by heat treatment. By increasing the horizontal magnetic field to greater than or equal to 50 mT, the discharge voltage decreases. Thereby, damages to the amorphous transparent conductive layer decreases and the residual stress can be made less than or equal 600 MPa. Further, before forming the amorphous transparent conductive layer on the polymeric film substrate 2, by heating the polymeric film substrate 2 in advance while adjusting the tension, the rate of dimensional change during the crystallization of the amorphous transparent conductive layer by a heat treatment can be decreased.

The transparent conductive film according to the present embodiment has been described above, but the present invention is not limited to the embodiment described above, and various modifications and alterations can be made based on the technical concept of the present invention

For example, the transparent conductive film of the embodiment described above is provided with a transparent conductive layer formed on the polymeric film substrate, but a dielectric layer may be provided between the polymeric film substrate and the transparent conductive layer. The dielectric layer may be a dielectric layer comprising an inorganic material such as NaF (1,3), Na₃AlF₆ (1.35), LiF (L36), MgF₂ (1.38), CaF₂ (1.4), BaF₂ (1.3), BaF₂ (1.3), SiO₂ (1.46), LaF₃ (1.55), CeF (1.63), Al₂O₃ (1.63) [numerical values in parentheses indicate refractive indices], a dielectric layer comprising an organic material having a refractive index of about 1.4 to 1.6 such as an acrylic resin, an urethane resin, a melamine resin, an alkyd resin, a siloxane-based polymer, and an organosilane condensate, or a dielectric layer comprising a mixture of the above-mentioned inorganic material and the above-mentioned organic material. The thickness of the dielectric layer can be determined as appropriate within a preferable range, and it is preferably 15 nm to 1500 nm, more preferably 20 nm to 1000 nm, and further preferably 20 nm to 800 nm. Within the above-mentioned range, the surface roughness can be sufficiently suppressed.

It is preferable that a dielectric layer formed of an organic material or a mixture of an inorganic material and an organic material is formed on the polymeric film substrate 2 by a wet coating method (e.g., gravure coating method). By wet coating, the surface roughness of the polymeric film substrate 2 can be decreased and can contribute to a decrease in specific resistance. The thickness of the organic dielectric layer can be determined as appropriate within a preferable range and it is preferably 15 nm to 1500 nm, more preferably 20 nm to 1000 nm, and further preferably 20 nm to 800 nm. Within the above-mentioned range, the surface roughness can be sufficiently suppressed. The dielectric layer may be a laminate of a plurality of layers of two or more different kinds of organic materials or mixtures of an inorganic material and an organic material having refractive indices differing by 0.01 or more.

A method of forming a dielectric layer comprising an organic material or a dielectric layer comprising a mixture of an inorganic material and an organic material on a polymeric film substrate by wet coating may be, for example, a method including applying, on a polymeric film substrate, a diluted composition obtained by diluting an organic material or a mixture of an inorganic material and an organic material with a solvent, and thereafter performing a heat treatment. This heat treatment can be considered as the aforementioned pre-annealing process. In other words, heat treatment that is performed along with the formation of the dielectric layer may be employed as the aforementioned pre-annealing. In the manufacture of the transparent conductive film, pre-annealing may of course be carried out separately from heat treatment hat is performed along with the manufacture of the dielectric layer.

It is preferable that an inorganic dielectric layer composed of an inorganic material is formed on the polymeric film substrate 2 by a vacuum film formation method (e.g., a sputtering method and a vacuum deposition method). By forming an inorganic dielectric layer having a high density by a vacuum film formation method, water or an impurity gas such as an organic gas released from the polymeric film substrate can he suppressed when forming the transparent conductive layer 3 by sputtering. As a result, an amount of impurity gas taken into the transparent conductive layer can be decreased, which can contribute to suppression of the specific resistance. The thickness of the inorganic dielectric layer is preferably 25 nm to 100 nm, more preferably 3 nm to 50 nm, and further preferably 4 nm to 30 nm. Within the aforementioned range, the release of an impurity gas can he sufficiently suppressed. Also, the inorganic dielectric layer may include a plurality of laminated layers of two or more kinds of inorganic materials having refractive indices differing by 0.01 or more.

Also, the dielectric layer may he a combination of an organic dielectric layer and an inorganic dielectric layer. By combining an organic dielectric layer and an inorganic dielectric layer, a substrate having a smooth surface and capable of inhibiting an impurity gas during sputtering is obtained, and the specific resistance of the crystalline transparent conductive layer can be reduced effectively. The thickness of each of an organic dielectric layer and an inorganic dielectric layer can he determined as appropriate within the ranges described above.

### EXAMPLES

Examples of the present invention will be described below,

### Example 1

### (Polymeric Film Substrate)

As a polymeric film substrate, a polyethylene terephthalate (PET) film maw (thickness 125 μm) manufactured by Mitsubishi Plastics, Inc. was used,

### (Formation of Organic Dielectric Layer)

A heat curing type resin composition containing a condensation of melamine resin: alkyd resin: organosilane at a weight ratio of 2:2:1 in solid content diluted with methyl ethyl ketone, such that its solid content concentration is 8% by weight, The obtained diluted composition was applied to one of the main surfaces of the film while conveying the aforementioned PET film in a roll-to-roll manner, and thermally cured at 150° C. for two minutes to form an organic dielectric layer having a film thickness of 35 nm.

### (Degasification)

The obtained PET film with an organic dielectric layer was placed in a vacuum sputtering apparatus and wound up by driving the film with the film being closely attached to a heated film formation roll. While driving the film, an atmosphere having a degree of vacuum of 1×10⁻⁴ Pa was obtained by an exhaust system provided with a cryocoil and a turbo-molecular pump.

### (Sputter Film Formation Using ITO Target)

On the aforementioned PET film with an organic dielectric layer, a SiO₂ layer serving as art inorganic dielectric layer and having a thickness of 5 nm was formed by DC sputtering while maintaining vacuum. On this inorganic dielectric layer, using a target material of indium tin oxide (hereinafter, ITO) having a tin oxide concentration of 10% by weight, an amorphous film of ITO (first ITO layer) having a thickness of 20 nm was formed by a RF superposition DC magnetron sputtering method (RF frequency 13.56 MHz, discharge voltage 150 V, ratio of the RF electric power to the DC electric power (RF electric power/DC electric power) 0.8, substrate temperature 130° C.) that is performed under a reduced pressure (0.4 Pa) in which Ar and O₂ (O₂ flow ratio of 0.1%) are introduced and with a horizontal magnetic field of 100 mT. On this first ITO layer, using a target material of ITO having a tin oxide concentration of 3% by weight, an amorphous film of ITO (second ITO layer) having a thickness of 5 nm was formed by an RE superposition DC magnetron sputtering method (RE frequency 13.56 MHz, discharge voltage 150 V, ratio of RF power to DC power (RF power/DC power) 0.8, substrate temperature 130° C.) that is performed under reduced pressure (0.40 Pa) in which Ar and O₂ (O₂ flow ratio 0.1%) are introduced and with a horizontal magnetic field of 100 mT.

### (Crystallization Process)

Subsequently, the polymeric film substrate on which the amorphous layers of ITO are formed was removed from the sputtering apparatus and heat-treated in an oven at 150° C. for 120 minutes. A transparent conductive film was obtained that includes a transparent conductive layer to crystalline material layer of ITO) having a thickness of 25 nm formed on the polymeric film substrate.

### Example 2

A transparent conductive layer was obtained in a manner similar to Example 1 except that a target material of ITO having a tin oxide concentration of 10% by weight was used and a single-layered transparent conductive film having a thickness of 25 nm was formed.

### Example 3

A transparent conductive film was obtained in a manner similar to Example 2 except that an organic dielectric layer than was not formed on the polymeric film substrate.

### Example 4

A transparent conductive film was obtained in a manner similar to Example 1 except that an inorganic dielectric layer was not formed on the polymeric film substrate and that a DC power supply was used as a sputtering power supply and the discharge voltage was 235 V.

### Example 5

A transparent conductive film was obtained in a manner similar to Example 2 except that an inorganic dielectric layer was not formed on the polymeric film substrate.

### Example 6

A transparent conductive film was obtained in a manner similar to Example 2 except that an organic dielectric layer and an inorganic dielectric layer were not formed on the polymeric film substrate and that the transparent conductive layer had a thickness of 30 nm.

### Example 7

A transparent conductive film was obtained in a manner similar to Example 6 except that the transparent conductive layer had a thickness of 35 nm.

### Example 8

A transparent conductive film was obtained in a manner similar to Example 5 except that heating was performed while adjusting the tension when forming an organic dielectric layer.

### Comparative Example 1

A transparent conductive film was obtained in a manner similar to Example 4 except that the horizontal magnetic field was 30 mT, the discharge voltage was 450 V using a DC power supply as a sputtering power supply, and forming a single-layered transparent conductive layer having a thickness of 25 nm without for an organic dielectric layer on a polymeric film substrate.

### Comparative Example 2

A transparent conductive film was obtained m a manner similar to Comparative Example 1 except that an organic dielectric layer was formed on a polymeric film substrate.

Thereafter, the transparent conductive film of Examples 1 to 8 and Comparative Examples 1 and 2 were measured and evaluated by the following method.

(1) Evaluation of Crystallization

A transparent laminated body including an amorphous ITO layer formed on a polymeric film substrate was heated with a hot air oven at 150° C. to undergo a crystallizing process, and immersed in hydrochloric acid of concentration of 5% by weight for 15 minutes, and thereafter rinsed with water and dried, and a resistance between terminals at a 15 mm interval was measured with a tester. Herein, in a case where the resistance between the terminals with a 15 mm interval is not excessive of 10 kΩ after immersion into hydrochloric acid, rinsing with water and drying, it was assumed that crystallization of an amorphous ITO layer is complete. Also, the measurement described above was carried out every 60 minutes of the heating time, and the time for which completion of crystallization was observed was evaluated as a crystallization time.

(2) Residual Stress

The residual stress was indirectly obtained from crystal lattice distortion of the transparent conductive layer by an X-ray scattering method. Using an X-ray powder diffractometer manufactured by Rigaku Corporation, a diffraded intensity was measured every 0.04° within a range of measurement scattering angle of 2θ=59° to 62°. An integrated time (exposure time) for each measurement angle was 100 seconds. The crystal lattice interval d of the transparent conductive layer was calculated using a peak (peak of the (622) plane of ITO) angle 2θ of the obtained diffraction image and a wavelength λ of the X-ray source, and calculated lattice strain ε based on d. Equations (1) and (2) indicated below were used in calculation.

[Math. 1]

2d sin θ=λ (1)

ε=(d−d_{c})/d₀ (2)

Here, λ is a wavelength (=0.15418 nm) of the X-ray source (Cu Kα radiation), and d₀ is a crystal lattice interval (=0.15241 nm) of the ITO layer in an unstressed state. Note that d₀ is a value obtained from ICDD (The International Centre for Diffraction Data) data base. Defining Ψ as an angle formed by the normal to the film surface and the normal to the ITO crystal plane, X-ray diffraction measurement described above was performed for each of Ψ=45°, 50°, 55°, 60°, 65°, 70°, 77°, and 90°, and a lattice strain ε was calculated for each Ψ. Note that the angle Ψ formed by the normal to the film surface and the normal to the ITO crystal plane was adjusted by rotating the sample by taking the TD direction as a central axis of rotation. A residual stress σ in an in-plane direction of the ITO layer was obtained using Equation (3) below from the gradient of the straight line of plots of the relationship between sin² Ψ and a lattice strain ε.

$$\begin{matrix}[ Math . 2 ] & \\ ɛ = \frac{1 + v}{E} σ {sin}^{2} Ψ - \frac{2 v}{E} σ & ( 3 )\end{matrix}$$

In the above equation, E is Young's modulus (116 GPa) of ITO, and v is Poisson's ratio (0.35). These values are known actual values described in D. G. Neerinck and T. J. Vimk, “Depth profiling of thin ITO films by grazing incidence X-ray diffraction”, Thin Solid Films, 278 (1996), P 1247.

(3) Maximum Rate of Dimensional Change

On a surface of the amorphous ITO layer formed on the polymeric film substrate, two gauge marks (flaws) were formed at an approximately 80 mm interval in a conveying direction (hereinafter, an MD direction) during the formation of the layer, and, the gauge length L₀ before crystallization and the gauge length L after heating were measured with a two-dimensional length gauge. The maximum rate of dimensional change (%) was obtained using 100×(L−L₀)/L₀.

(4) Thickness

Using an X-ray reflectivity method as a measurement principle, the thickness of the transparent conductive layer was calculated by measuring an X-ray reflectivity with a powder X-ray diffractometer (manufactured by Rigaku Corporation, “RINT-2000”) under the following measurement conditions, and calculated by analyzing the obtained measurement data with an analyzing software available from Rigaku Corporation, “GXRR3”). The thickness of the transparent conductive layer was analyzed with analysis conditions as indicated below, using a two-layer model including a polymeric film substrate and an ITO layer having a density of 7.1 g/cm³, and performing a least square fitting by taking the thickness and the surface roughness of an ITO layer as variables.

### [Measurement Conditions]

Light Source: Cu—Kα radiation wavelength: 1, 5418 Å), 40 kV, 40 mA

Optical System: collimated beam optical system

Divergence Slit: 0.05 mm

Light Receiving Slit 0.05 mm

Monochromatization and Parallelization: multi-layer Goebel mirror

Measurement Mode: θ/2θ scan mode

Measurement Range (2θ): 0.3 to 2.0°

### [Analysis Conditions]

Analytical Method: least square fitting

Measurement Range (2θ): 2θ=0.3 to 2.0°

(5) Specific Resistance

A surface resistance (Ω/□) of the transparent conductive layer was measured by a four-point probe method in conformity with JIS K7194 (1994). A specific resistance was calculated from the thickness of the transparent conductive layer obtained by the method mentioned in the aforementioned section (4) and the surface resistance.

(6) Rate of Change of Resistance

A rectangle of 10 mm×150 mm, the long sides being in a MD direction, was cut out from the transparent conductive film, and silver paste was screen-printed with a width of 5 mm at each short side and heated at 140° C. for 30 minutes to form silver electrodes. The resistance (initial resistance R₀) of this test piece was obtained by a two-point probe method.

The test piece was made to curve along a cork borer having a boring diameter of 9.5 mmφ and held for ten seconds with a load of 500 g. Thereafter, resistance RT was measured and a rate of change with respect to the initial resistance (rate of change of resistance) RT/R₀ was obtained. When the value is greater than or equal to 5, it is determined that the flexibility was poor, and when the value is less than 5, it is determined that the flexibility is good. The test was carried out for both a case in which the surface on which an ITO layer is formed is facing outward and a case in which the surface on which an ITO layer is formed is facing inward, and the case for which the flexibility was poor was employed.

Results measured by the methods described in the aforementioned sections (1) to (6) are shown in Table 1.

TABLE 1

| | | HORIZONTAL | | | | | INORGANIC |
|---|---|---|---|---|---|---|---|
| | | MAGNETIC | DISCHARGE | ATMOSPHERIC | | ITO LAYER | DIELECTRIC |
| | SPUTTERING | FIELD | VOLTAGE | PRESSURE | ITO | THICKNESS | LAYER |
| | METHOD | [ml] | [V] | [Pa] | CONFIGURATION | [nm] | [nm] |
| EXAMPLE 1 | DC/RF | 100 | 150 | 0.4 | DOUBLE | 25 | 5 |
| | | | | | LAYERED | | |
| EXAMPLE 2 | DC/RF | 100 | 150 | 0.4 | SINGLE | 25 | 5 |
| | | | | | LAYERED | | |
| EXAMPLE 3 | DC/RF | 100 | 150 | 0.4 | SINGLE | 25 | 5 |
| | | | | | LAYERED | | |
| EXAMPLE 4 | DC | 100 | 235 | 0.4 | DOUBLE | 25 | — |
| | | | | | LAYERED | | |
| EXAMPLE 5 | DC/RF | 100 | 150 | 0.4 | SINGLE | 25 | — |
| | | | | | LAYERED | | |
| EXAMPLE 6 | DC/RF | 100 | 150 | 0.4 | SINGLE | 30 | — |
| | | | | | LAYERED | | |
| EXAMPLE 7 | DC/RF | 100 | 150 | 0.4 | SINGLE | 35 | — |
| | | | | | LAYERED | | |
| EXAMPLE 8 | DC/RF | 100 | 150 | 0.4 | SINGLE | 25 | — |
| | | | | | LAYERED | | |
| COMPARATIVE | DC | 30 | 450 | 0.4 | SINGLE | 25 | — |
| EXAMPLE 1 | | | | | LAYERED | | |
| COMPARATIVE | DC | 30 | 450 | 0.4 | SINGLE | 25 | — |
| EXAMPLE 2 | | | | | LAYERED | | |

| | ORGANIC | MAXIMUM RATE | | SURFACE | | | CRYSTAL- |
|---|---|---|---|---|---|---|---|
| | DIELECTRIC | OF DIMENSIONAL | RESIDUAL | RESISTANCE | SPECIFIC | RATE OF CHANGE | LIZATION |
| | LAYER | CHANGE | STRESS | VALUE | RESISTANCE | OF RESISTANCE | TIME |
| | [nm] | [%] | [MPa] | [Ω/□] | [Ω · cm] | [MULTIPLE] | [min] |
| EXAMPLE 1 | 35 | −0.5 | 315 | 55 | 1.4 × 10⁻⁴ | 1.0 | 60 |
| EXAMPLE 2 | 35 | −0.5 | 330 | 55 | 1.4 × 10⁻⁴ | 1.0 | 120 |
| EXAMPLE 3 | — | −1.0 | 554 | 70 | 1.8 × 10⁻⁴ | 3.0 | 120 |
| EXAMPLE 4 | 35 | −0.5 | 380 | 90 | 2.1 × 10⁻⁴ | 1.0 | 60 |
| EXAMPLE 5 | 35 | −0.5 | 330 | 70 | 1.7 × 10⁻⁴ | 1.0 | 120 |
| EXAMPLE 6 | — | −1.0 | 530 | 60 | 1.8 × 10⁻⁴ | 3.5 | 120 |
| EXAMPLE 7 | — | −1.0 | 535 | 50 | 1.8 × 10⁻⁴ | 4.0 | 120 |
| EXAMPLE 8 | 35 | −0.8 | 475 | 70 | 1.7 × 10⁻⁴ | 2.0 | 120 |
| COMPARATIVE | — | −1.0 | 639 | 130 | 3.2 × 10⁻⁴ | 6.0 | 120 |
| EXAMPLE 1 | | | | | | | |
| COMPARATIVE | 35 | −1.0 | 620 | 125 | 3.1 × 10⁻⁴ | 5.5 | 120 |
| EXAMPLE 2 | | | | | | | |

As shown in Table 1, it can he seen that the transparent conductive films of Examples 1 to 8 have an excellent flex durability, since the ITO layer has a low residual stress of less than or equal to 600 MPa, a low specific resistance of less than or equal to 2.2×10⁻⁴ Ω·cm, a small thickness of 25 nm to 35 nm and a rate of change of resistance of less than 5. Accordingly, cracks can be prevented from occurring in the surface of the ITO layer during manufacture.

On the other hand, it can he seen that the conductive films of Comparative Examples 1 and 2 are inferior in flex durability, since the ITO layer has a residual stress of greater than or equal to 620 MPa, a high specific resistance of greater than or equal to 3.1×10⁻⁴ Ω·cm and a rate of change of resistance of greater than or equal to 5.5.

Therefore, it can be seen that, with the transparent conductive film of the present invention, cracks can be prevented from occurring, since the transparent conductive layer has a residual stress of less than or equal to 600 MPa, and has an excellent flex durability.

### INDUSTRIAL APPLICABILITY

The type of use of the transparent conductive film according the present invention is not particularly limited, and preferably used for a capacitive touch panel sensor used in portable devices such as smartphones or tablet-type devices (also referred to as Slate PCs).

### LIST OF REFERENCE SIGNS

1 transparent conductive film
2 polymeric film substrate
2a main surface.
3 transparent conductive layer

1. A transparent conductive film comprising:
a polymeric film substrate; and a transparent conductive layer on at least one of main surfaces of the polymeric film substrate,
the transparent conductive layer being a crystalline Transparent conductive layer comprising an indium tin composite oxide,
the transparent conductive layer having a residual stress of less than or equal to 600 MPa,
the transparent conductive layer having a specific resistance of 1.1×10⁻⁴ Ω·cm to 3.0×10⁻⁴ Ω·cm,
the transparent conductive layer having a thickness of 15 nm to 40 nm.

2. The transparent conductive film according to claim 1, wherein the transparent conductive layer has a specific resistance of 1.1×10⁻⁴ Ω·cm to 2.2×10⁻⁴ Ω·cm.

3. The transparent conductive film according to claim 1, wherein the transparent conductive layer is a layer obtained by crystallizing, by heat treatment, an amorphous transparent conductive layer provided on the polymeric film substrate, and a maximum rate of dimensional change of the transparent conductive layer in a plane thereof is −1.0% to 0% with respect to the amorphous transparent conductive layer.

4. The transparent conductive film according to claim 1, wherein the transparent conductive film has an elongated shape and is wound into a roll.

5. The transparent conductive film according to claim 3, wherein the amorphous transparent conductive layer is crystallized at 110° C. to 180° C. for less than or equal to 150 minutes.

6. The transparent conductive film according to claim 1, wherein the transparent conductive layer has a ratio of tin oxide of 0.5% to 15% by weight, the ratio of tin oxide being represented by {tin oxide/(indium oxide+tin oxide)}×100(%).

7. The transparent conductive film according to claim 1, wherein the transparent conductive layer is a double layered film including a first indium-tin composite oxide layer and a second indium-tin composite oxide layer laminated in this order from the polymeric film substrate side,
the first indium-tin composite oxide layer has a tin oxide content of 6% to 15% by weight, and
the second indium-tin composite oxide layer has a tin oxide content of 0.5% to 5.5% by weight.

8. The transparent conductive film according to claim 1, wherein the transparent conductive layer is a triple layered film including a first indium-tin composite oxide layer, a second indium-tin composite oxide layer and a third indium-tin composite oxide layer laminated in this order from the polymeric film substrate side,
the first indium-tin composite oxide layer has a tin oxide content of 0.5% to 5.5% by weight,
the second indium-tin composite oxide layer has a tin oxide content of 6% to 15% by weight, and
the third indium-tin composite oxide layer has a tin oxide content of 0.5% to 5.5% by weight.

9. The transparent conductive film according to claim 1, further comprising an organic dielectric layer formed by a wet this forming method, wherein the organic dielectric layer is provided on at least one of the main surfaces of the polymeric film substrate, and the transparent conductive layer is provided on the organic dielectric layer.

10. The transparent conductive film according to claim 1, further comprising an inorganic dielectric layer formed by a vacuum film formation method, wherein the inorganic dielectric layer is provided on at least one of the main surfaces of the polymeric film substrate, and the transparent conductive layer is provided on the inorganic dielectric layer.

11. The transparent conductive trim according to claim 1, further comprising an organic dielectric layer formed by a wet film formation method and an inorganic dielectric layer formed by a vacuum film formation method, and wherein the organic dielectric layer, the inorganic dielectric layer, and the transparent conductive layer are provided on at least one of the main surfaces of the polymeric film substrate in this order.

12. A method of manufacturing a transparent conductive film including a polymeric film substrate and a transparent conductive layer on at least one of main surfaces of the polymeric film substrate, the transparent conductive layer being a crystalline transparent conductive layer comprising an indium tin composite oxide, the transparent conductive layer having a residual stress of less than or equal to 600 MPa, the transparent conductive layer having a specific resistance of 1.1×10⁻⁴ Ω·cm to 3.0×10⁻⁴ Ω·cm, the transparent conductive layer having a thickness of 15 nm to 40 nm, the method comprising:
forming an amorphous transparent conductive layer on the polymeric film substrate by a magnetron sputtering method using a target of an indium tin composite oxide with a horizontal magnetic field at a surface of the target being greater than or equal to 50 mT; and
crystallizing the amorphous transparent conductive layer by heat treatment.

13. The method of manufacturing a transparent conductive film according to claim 12, wherein, the magnetron sputtering method is a RF superposition DC magnetron sputtering method.

14. The method of manufacturing a transparent conductive film according to claim 12, further comprising a step of heating the polymeric film substrate before the forming of the amorphous transparent conductive layer.
